(19) United States
(12) Patent Application Publication
(10) Pub. No.: US 2020/0294768 A1
(43) Pub. Date: Sep. 17, 2020

(54) PLASMA PROCESSING APPARATUS AND ETCHING METHOD

(71) Applicant: TOSHIBA MEMORY CORPORATION, Minato-ku (JP)

(72) Inventor: Takashi Ohashi, Yokkaichi (JP)

(73) Assignee: TOSHIBA MEMORY CORPORATION, Minato-ku (JP)

(21) Appl. No.: 16/558,548

(22) Filed: Sep. 3, 2019

(30) Foreign Application Priority Data
Mar. 15, 2019 (JP) 2019-048799

(51) Int. Cl. H01J 37/32

(52) U.S. Cl. CPC H01J 37/3266; H01J 2237/334; H01J 37/32715

(57) ABSTRACT

According to one embodiment, a plasma processing apparatus includes a chamber, a substrate stage configured to support a substrate inside the chamber, and a plasma generation structure configured to generate plasma processing the substrate, in a space above the substrate inside the chamber. Further, the plasma processing apparatus includes an electromagnet including coils configured to apply a magnetic field to the space, and an electromagnet controller configured to cause pulsed electric currents, in each of which its direction and ON/OFF are pulsed, to flow through the coils.

### CROSS-REFERENCE TO RELATED APPLICATIONS

This application is based upon and claims the benefit of priority from Japanese Patent Application No. 2019-048799, filed on Mar. 15, 2019; the entire contents of which are incorporated herein by reference.

### FIELD

An embodiment described herein relates generally to a plasma processing apparatus and an etching method.

### BACKGROUND

A plasma processing apparatus is known in which an electric field and a magnetic field are applied to a process gas supplied between two electrodes to generate plasma, and this plasma is used to perform a process to a processing object mounted on one of the electrodes.

### BRIEF DESCRIPTION OF THE DRAWINGS

FIG. 1 is a sectional view schematically illustrating a configuration example of a plasma processing apparatus according to an embodiment;

FIGS. 2A and 2B are diagrams schematically illustrating the mechanism of operation of an electric current control unit;

FIG. 3 is a diagram illustrating an example of sequence control information;

FIGS. 4A and 4B are diagrams schematically illustrating the relationship of electric currents flowing through coils with magnetic fields;

FIGS. 5A and 5B are diagrams schematically illustrating an example of an etching process according to the embodiment;

FIGS. 6A and 6B are diagrams illustrating examples of the sectional shape of a hole according to the embodiment;

FIG. 7 is a sectional view schematically illustrating another configuration example of a plasma processing apparatus according to the embodiment; and

FIG. 8 is a top view schematically illustrating an example of a coil shape.

### DETAILED DESCRIPTION

In general, according to one embodiment, a plasma processing apparatus includes a chamber, a substrate stage configured to support a substrate inside the chamber, and a plasma generation structure configured to generate plasma processing the substrate, in a space above the substrate inside the chamber. Further, the plasma processing apparatus includes an electromagnet including coils configured to apply a magnetic field to the space, and an electromagnet controller configured to cause pulsed electric currents, in each of which its direction and ON/OFF are pulsed, to flow through the coils.

An exemplary embodiment of a plasma processing apparatus and an etching method will be explained below in detail with reference to the accompanying drawings. The present invention is not limited to the following embodiment.

The density of the plasma is preferably uniform, but is difficult to control to be uniform in practice. For example, in an etching process using plasma, non-uniformity of the plasma density causes holes to be formed in a state tilted relative to the vertical direction.

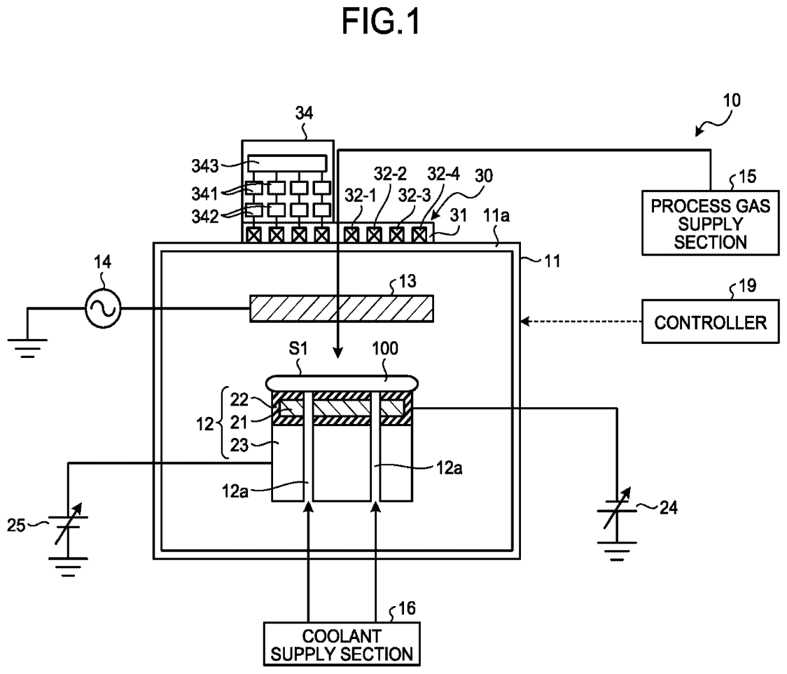

FIG. 1 is a sectional view schematically illustrating a configuration example of a plasma processing apparatus according to an embodiment. Here, an explanation will be given of a case where the plasma processing apparatus is exemplified by a plasma etching apparatus.

The plasma processing apparatus 10 includes a chamber 11, an Electrostatic Chuck (ESC) 12 serving as a substrate stage, an upper electrode 13, an Alternating Current (AC) power supply 14, a process gas supply section 15, a coolant supply section 16, and a controller 19. The ESC 12, the upper electrode 13, the AC power supply 14, and the process gas supply section 15 provide an example of a plasma generation structure. The coolant supply section 16 is an example of a gas supply unit. The ESC 12 includes a High Voltage (HV) electrode (lower electrode) 21, an insulating film 22, an ESC base 23, an HV power supply 24, and an ESC power supply 25.

The chamber 11 has a cylindrical shape, for example, and is configured to accommodate a substrate 100, such as a wafer, to be treated as a processing object. The ESC 12 serves to hold the substrate 100 inside the chamber 11. While the upper electrode 13 is disposed outside the ESC 12, the HV electrode 21 is disposed inside the ESC 12. The HV electrode 21 is covered with the insulating film 22, and is arranged above the ESC base 23. The HV power supply 24 is a variable voltage source for adjusting the electric potential of the HV electrode 21. The ESC power supply 25 is a variable voltage source for adjusting the electric potential of the ESC base 23. The substrate 100 is mounted above the HV electrode 21 with the insulating film 22 interposed therebetween. The ESC 12 attracts and holds the substrate 100 by the HV electrode 21 with an electrostatic force. The ESC 12 includes an upper face for mounting the substrate 100 thereon, a lower face opposite to the upper face, and a lateral face. The ESC 12 is configured to move the substrate 100 up and down by a plurality of pins (not illustrated) provided at the upper face of the ESC 12.

The upper electrode 13 is disposed above the HV electrode 21. For example, the upper electrode 13 is arranged in parallel with the HV electrode 21. The upper electrode 13 is provided with through-holes (not illustrated) to supply a process gas from the process gas supply section 15 into the space between the upper electrode 13 and the HV electrode 21. For example, the upper electrode 13 is formed of a plate member including a plurality of through-holes that extend therethrough in the thickness direction. The plasma processing apparatus 10 is configured to generate plasma between the upper electrode 13 and the HV electrode 21, and to supply the plasma toward the front face S1 of the substrate 100 to process the substrate 100 by the plasma. Specifically, the front face S1 of the substrate 100 is etched by dry etching using the plasma.

The AC power supply 14 serves to supply an AC current to the upper electrode 13. Consequently, plasma is generated between the upper electrode 13 and the HV electrode 21.

The process gas supply section 15 serves to supply a process gas for plasma generation into the chamber 11. The upper electrode 13 and the HV electrode 21 use the AC current from the AC power supply 14 to generate plasma of the process gas.

The coolant supply section 16 serves to supply a coolant to the substrate 100 through a plurality of flow passages 12a formed in the ESC 12. The coolant is an inactive gas, such as a rare gas, which is, for example, helium (He) gas.

The controller 19 is configured to control the operation of the plasma processing apparatus 10. For example, the controller 19 controls the operation of the chamber 11, the operation of the ESC 12, the ON/OFF and/or electric current of the AC power supply 14, the ON/OFF and/or process gas supply amount of the process gas supply section 15, the ON/OFF and/or coolant supply amount of the coolant supply section 16, and so forth.

Further, the plasma processing apparatus 10 includes an electromagnet 30 above the top plate 11a of the chamber 11. The electromagnet 30 includes a core member 31 and a plurality of coils 32-1 to 32-4. In the example illustrated here, four ring coils 32-1 to 32-4 arranged in order from inside are set in a concentric state such that the center of the coils agrees with the center of the top plate 11a. Hereinafter, when the respective coils 32-1 to 32-4 do not need distinction, each of the coils will be referred to as “coil 32”.

Further, the respective coils 32 are connected to an electromagnet controller 34. The electromagnet controller 34 includes plasma control units 341, electric current control units 342, and a sequence control unit 343. Each of the plasma control units 341 serves to control the intensity of a magnetic field to be generated by the corresponding coil 32. More specifically, each plasma control unit 341 supplies an electric current of a predetermined magnitude to the corresponding coil 32 during one plasma process, under the control of the sequence control unit 343. Further, each plasma control unit 341 can change the direction of an electric current caused to flow through the corresponding coil 32. Every coil 32 may be provided with one plasma control unit 341, or a plurality of coils 32 may be provided with one common plasma control unit 341. In the latter case, the plasma control unit 341 is configured to individually control the direction and magnitude of an electric current to be given to each coil 32.

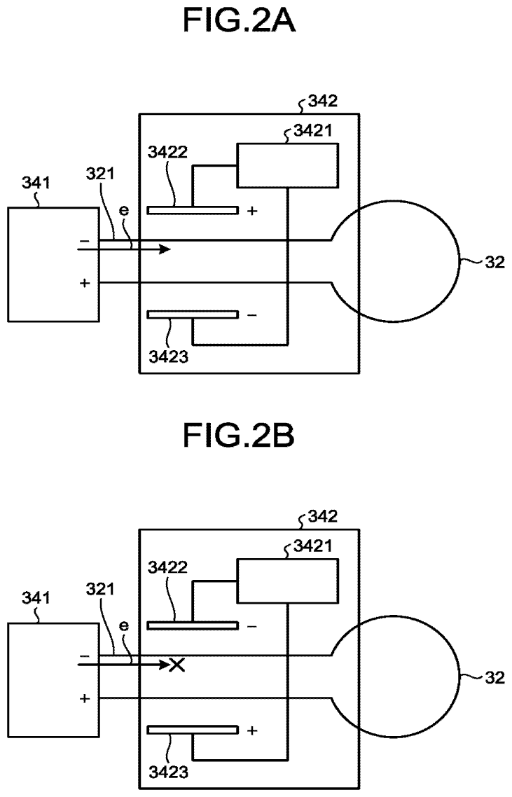

Each of the electric current control units 342 serves to switch the ON/OFF of an electric current to be supplied from the corresponding plasma control unit 341 to the coil 32, under the control of the sequence control unit 343. FIGS. 2A and 2B are diagrams schematically illustrating the mechanism of operation of each electric current control unit. For example, each electric current control unit 342 includes a power supply 3421 and electrodes 3422 and 3423 connected to the power supply 3421.

As illustrated in FIG. 2A, in a state where a constant electric current is flowing through the coil 32, the power supply 3421 applies a positive bias voltage between the electrodes 3422 and 3423 such that the electrode 3422 is higher than the electrode 3423 in electric potential. At this time, electrons flowing through a wiring line 321 connecting the plasma control unit 341 to the coil 32 are attracted by the positive bias voltage applied by the electric current control unit 342, and an electric current is thereby caused to flow through the coil 32. As a result, a magnetic field is generated at the coil 32.

On the other hand, as illustrated in FIG. 2B, in a state where a constant electric current is flowing through the coil 32, the power supply 3421 applies a negative bias voltage between the electrodes 3422 and 3423 such that the electrode 3422 is lower than the electrode 3423 in electric potential. At this time, electrons flowing through the wiring line 321 receive a repulsive force due to the negative bias voltage applied by the electric current control unit 342, and the electric current is thereby caused to stop flowing through the coil 32. As a result, the magnetic field generated at the coil 32 disappears.

As described above, the electric current control unit 342 can switch the ON/OFF of an electric current caused to flow through the coil 32. Further, also when the direction of an electric current is changed by the plasma control unit 341, the electric current control unit 342 can switch the ON/OFF of the electric current similarly by inverting the sign of a voltage to be applied between the electrodes 3422 and 3423. As a result, the coil 32 comes to be supplied with a pulsed electric current obtained by pulsing.

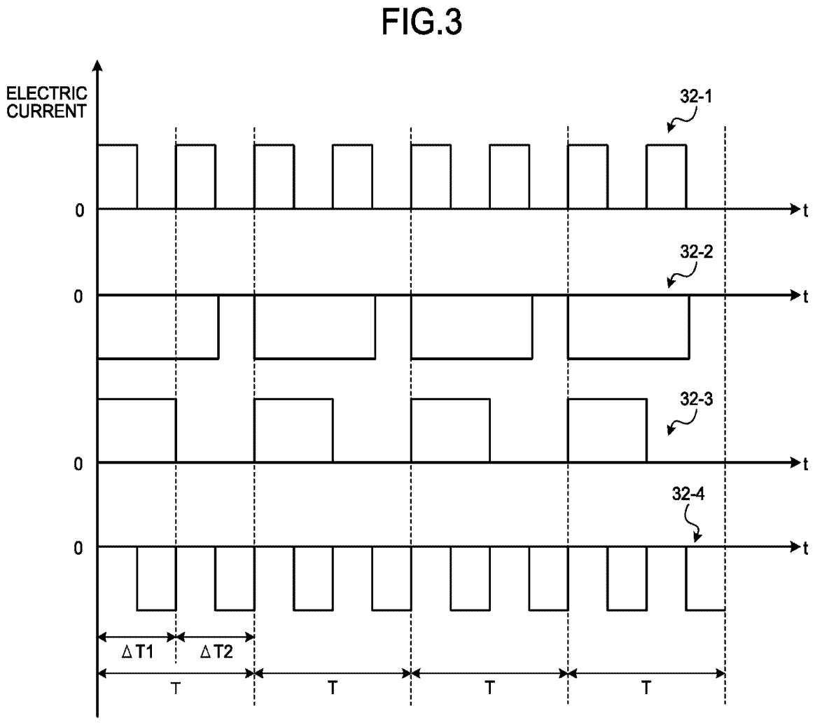

The sequence control unit 343 is configured to control the plasma control units 341 and the electric current control units 342 to pulse the ON/OFF and direction of electric currents to the respective coils 32 and to synchronize the electric currents with each other among the coils 32, in accordance with sequence control information. FIG. 3 is a diagram illustrating an example of the sequence control information. For example, the sequence control information is formed of a timing chart of pulsed electric currents caused to flow through the coils 32. In FIG. 3, the horizontal axis indicates the time, and the vertical axis indicates the electric current magnitude. Further, FIG. 3 illustrates pulsed electric currents to be given to the respective coils 32-1 to 32-4, in order from above. Here, the pulsed electric currents to be given to the respective coils 32-1 to 32-4 are different from each other in a single period T, and these pulsed electric currents are repeated periodically. Further, the starting time points of each period T at the respective coils 32-1 to 32-4 are set in synchronism with each other, under the control of the sequence control unit 343. Here, this T denotes a time period far shorter than the total processing time necessary for performing a plasma process, and has a length of several seconds or less, for example.

For the coil 32-1, positive electric current pulses are generated at regular intervals. At the beginning of each period T, a positive electric current pulse rises up. Each positive electric current pulse has a width of T/4, and each off-time also has a width of T/4.

For the coil 32-2, negative electric current pulses are generated. At the beginning of each period T, a negative electric current pulse rises up. Each negative electric current pulse has a width of 3T/4, and each off-time has a width of T/4.

For the coil 32-3, positive electric current pulses are generated. At the beginning of each period T, a positive electric current pulse rises up. Each positive electric current pulse has a width of T/2, and each off-time has a width of T/2.

For the coil 32-4, negative electric current pulses are generated at regular intervals. At the beginning of each period T, an off-time is first present, and then a negative electric current pulse rises up after the lapse of T/4. Each off-time has a width of T/4, and each negative electric current pulse also has a width of T/4.

In accordance with the sequence described above, the sequence control unit 343 controls the respective plasma control units 341, or the electric current control units 342 in addition to the plasma control units 341. Here, as illustrated in FIG. 3, adjacent coils 32 are preferably supplied with respective electric currents such that the directions of the electric currents are opposite to each other.

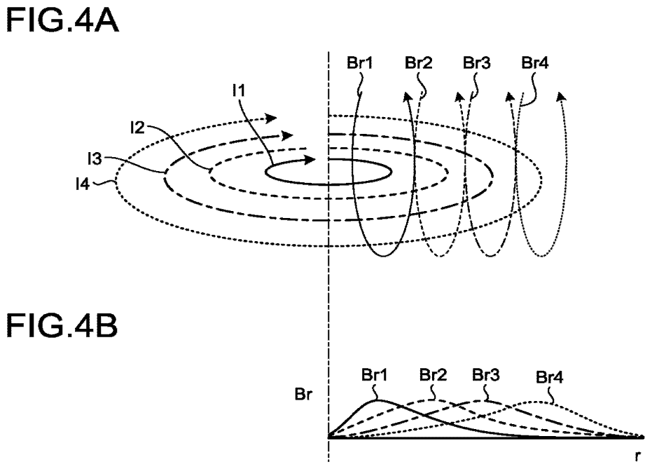

FIGS. 4A and 4B are diagrams schematically illustrating the relationship of electric currents flowing through the coils with magnetic fields. FIG. 4A is a diagram schematically illustrating the directions of the electric currents and the directions of the magnetic fields. FIG. 4B is a diagram illustrating an example of the magnitude of the magnetic fields generated by the respective coils above the processing face of the processing object.

As illustrated in FIG. 4A, when electric currents I1 to I4 are caused to flow through the coils 32-1 to 32-4 respectively, magnetic fields Br1 to Br4 are generated around the coils 32-1 to 32-4 in accordance with the right-handed screw rule. As illustrated in FIG. 4B, the magnetic fields Br1 to Br4 are formed above the processing face of the processing object by the electric currents I1 to I4 flowing through the respective coils 32-1 to 32-4. Here, the magnetic fields Br1 to Br4 given by the respective coils 32-1 to 32-4 are added up to form a magnetic field above the processing face. Here, when the magnitudes and/or directions of the electric currents I1 to I4 caused to flow through the coils 32-1 to 32-4 are changed, the magnitudes of the magnetic fields Br1 to Br4 by the respective coils 32-1 to 32-4 are changed, and thus the magnetic field above the processing face can be changed. As illustrated in FIG. 3, when the pulsed electric currents are caused to flow through the respective coils 32-1 to 32-4, the magnetic field above the processing face can be formed while being changed dynamically. Here, in general, as the intensity of the magnetic field is higher, the plasma density is increased.

For example, sequence control information such as that illustrated in FIG. 3 is obtained in the following way. First, the relationship between the magnetic field and the plasma density is obtained by a simulation. Then, on the basis of the simulation result, the direction, magnitude, and ON/OFF timing of each of the electric currents are obtained by experiments to obtain a desired plasma density by the plasma processing apparatus 10 in practice. Then, the direction, magnitude, and ON/OFF timing of each of the electric currents are collected for the respective coils 32, and the synchronization timing of the electric currents is further set, to obtain the sequence control information.

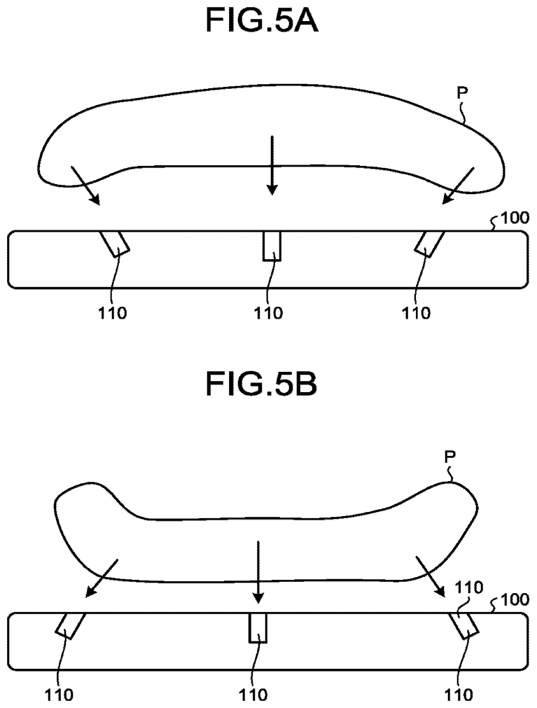

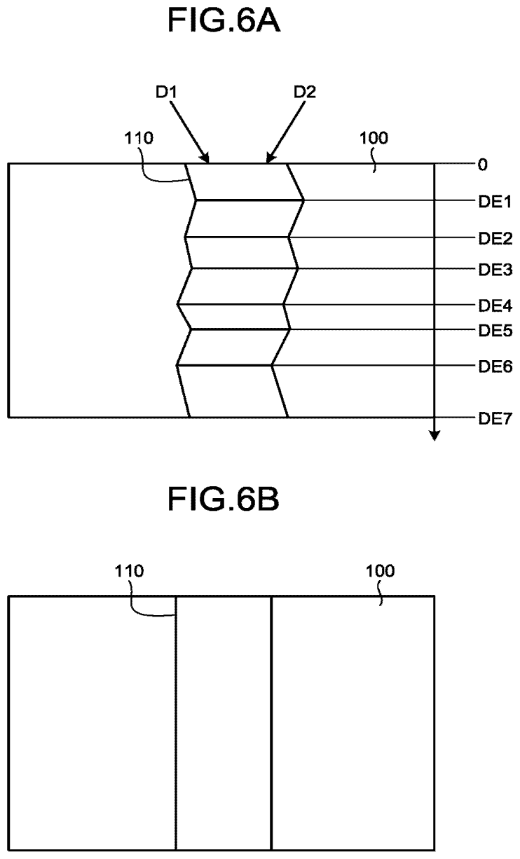

Next, an explanation will be given of an etching method to be performed by using this plasma processing apparatus 10. FIGS. 5A and 5B are diagrams schematically illustrating an example of an etching process according to the embodiment. FIGS. 6A and 6B are diagrams illustrating examples of the sectional shape of a hole according to the embodiment.

First, a substrate 100 to be treated as a processing object is mounted on the ESC 12 serving as a substrate stage. Then, a process gas is supplied from the process gas supply section 15 into the space between the substrate 100 and the upper electrode 13, and an AC current is supplied from the AC power supply 14 to the upper electrode 13. Further, the sequence control unit 343 controls at least one of the groups of the plasma control units 341 and the electric current control units 342, such that pulsed electric currents flow through the respective coils 32-1 to 32-4 of the electromagnet 30 in synchronism with each other, in accordance with the sequence control information. Consequently, a magnetic field having a predetermined intensity is generated between the ESC 12 and the upper electrode 13, and thus plasma is generated between the upper electrode 13 and the HV electrode 21. With the plasma thus generated, the substrate 100 is subjected to an etching process.

The plasma P generated at this time is assumed to have the shape illustrated in FIG. 5A. In general, it is preferable to form uniform plasma above the substrate 100. However, due to unevenness of the magnetic field in the space, it is difficult to generate uniform plasma above the substrate 100. For example, as illustrated in FIG. 5A, the plasma P is in a state where the region corresponding to the peripheral side of the substrate 100 is sagging down as compared with the region corresponding to the central side of the substrate 100. In the case of an etching process, ions fly out in directions perpendicular to surfaces that define the contour of the plasma P. As a result, in this example, holes 110 are formed to be perpendicular to the processing face of the substrate 100 on the central side of the substrate 100, but holes 110 are formed to be tilted outward, relative to the direction perpendicular to the processing face, on the peripheral side.

As illustrated in FIG. 5A, holes 110 are formed in a state tilted outward on the peripheral side of the substrate 100. In consideration of the above, according to this embodiment, after an etching step is performed for a predetermined time under first conditions set as described above, an etching step is performed under second conditions set to generate plasma P for causing holes 110 on the peripheral side of the substrate 100 to be tilted inward, i.e., in the opposite direction.

The plasma P generated at this time is assumed to have the shape illustrated in FIG. 5B. For example, as illustrated in FIG. 5B, the plasma P is in a state where the region corresponding to the central side of the substrate 100 is sagging down as compared with the region corresponding to the peripheral side of the substrate 100. As a result, in this example, holes 110 are formed to be perpendicular to the processing face of the substrate 100 on the central side of the substrate 100, but holes 110 are formed to be tilted inward, relative to the direction perpendicular to the processing face, on the peripheral side.

After the etching step is performed for a predetermined time under the second conditions set as described above, an etching step is performed under the first conditions set to generate plasma P for causing holes 110 on the peripheral side of the substrate 100 to be tilted outward, i.e., in the opposite direction. In this way, until the bottoms of holes 110 reach a desired depth, etching steps are repeatedly performed by alternately using the first conditions and the second conditions. However, for example, as shown in the sequence control information illustrated in FIG. 3, if the conditions, which include the ON/OFF timing, magnitude, and direction, of the pulsed electric currents to the respective coils 32-1 to 32-4 are not synchronized with each other, the plasma P illustrated in FIG. 5A and the plasma P illustrated in FIG. 5B cannot be alternately generated. Accordingly, it is important to synchronize the pulsed electric currents caused to flow through the respective coils 32-1 to 32-4 with each other.

As described above, the etching steps are alternately performed such that the etching directions become opposite to each other on the peripheral side of the substrate 100. In this case, as illustrated in FIG. 6A, a region etched in a first etching direction D1 and a region etched in a second etching direction D2 opposite to the first etching direction D1 are alternately formed in the depth direction. In FIG. 3, it is assumed that, where ΔT1 denotes the first half of each period T, and ΔT2 denotes the second half thereof, the etching in the first etching direction D1 is performed in ΔT1, and the etching in the second etching direction D2 is performed in ΔT2.

Consequently, for example, in ΔT1 of the first cycle, the etching in the first etching direction D1 is performed down to a depth DE1. Here, the reference of the depth direction is the position of the upper face of the substrate 100. In ΔT2 of the first cycle, the etching in the second etching direction D2 is performed from the depth DE1 to a depth DE2. Then, in ΔT1 of the second cycle, the etching in the first etching direction D1 is performed from the depth DE2 to a depth DE3. In ΔT2 of the second cycle, the etching in the second etching direction D2 is performed from the depth DE3 to a depth DE4. Thereafter, the substantially the same cycles are repeatedly performed. In this way, the etching in the first etching direction D1 and the etching in the second etching direction D2 are alternately performed, and a hole is thereby formed. The hole 110 thus formed comes to have a sidewall of a bellows-like shape.

Here, when each period T is set to several seconds or less, the etching amount by each period T becomes small. Thus, as illustrated in FIG. 6B, the hole 110 comes to have a sidewall that extends almost perpendicular to the processing face of the substrate 100.

When the etching reaches a predetermined depth, the etching sequence ends.

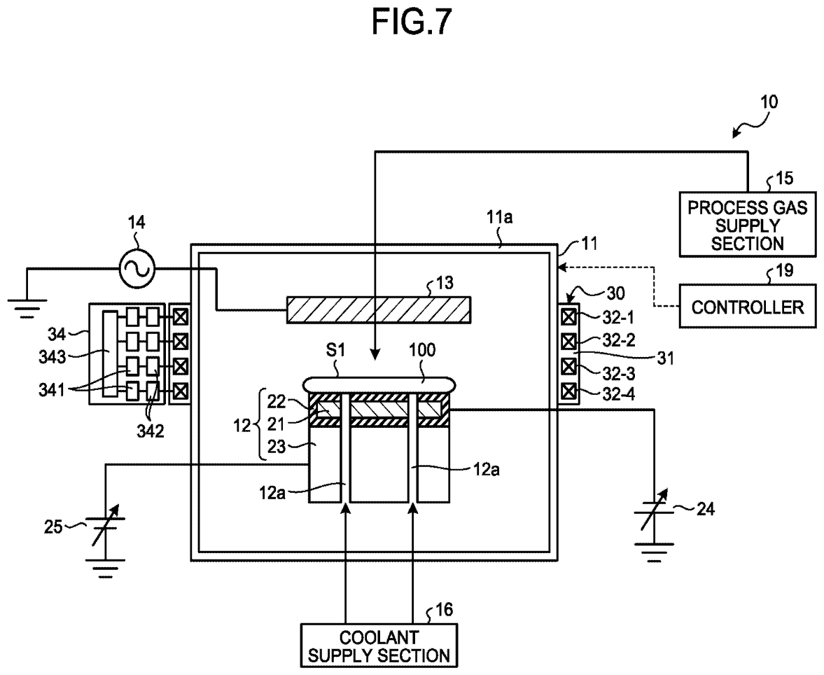

In the above description, a case is illustrated where the electromagnet 30 is arranged above the top plate 11a of the chamber 11. However, the embodiment is not limited to this example. The electromagnet 30 may be arranged at an arbitrary position of the chamber 11. FIG. 7 is a sectional view schematically illustrating another configuration example of a plasma processing apparatus according to the embodiment. FIG. 7 illustrates a case where an electromagnet 30 is arranged around the lateral face of the chamber 11. Also with this configuration, the distribution of a magnetic field above the upper face of the substrate 100 can be changed. Here, the constituent elements corresponding to those of FIG. 1 are denoted by the same reference symbols, and their description will be omitted.

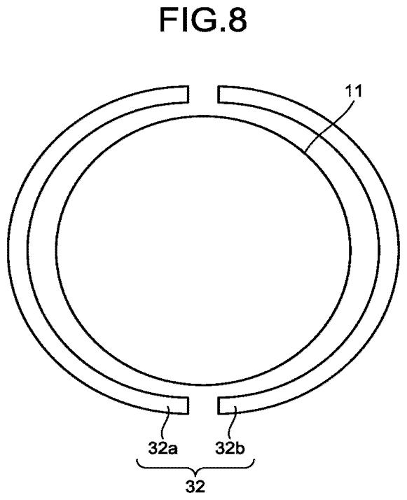

Further, in the above description, a case is illustrated where the coils 32 of the electromagnet 30 are arranged in a circular shape. However, the embodiment is not limited to this example. FIG. 8 is a top view schematically illustrating an example of a coil shape. Where “n” is an integer of 2 or more, a coil 32 is divided into an n-number of arc-shaped coil segments, such that the n-number of coil segments are arranged in a ring shape. In the case of FIG. 8, “n” is 2, and the coil 32 is divided into two coil segments 32a and 32b. Further, the two coil segments 32a and 32b are arranged around the chamber 11 and form a single ring. Here, each of the coil segments 32a and 32b may be provided with a plasma control unit 341 and an electric current control unit 342. Alternatively, all the coil segments 32a and 32b may be provided with a plasma control unit 341 and an electric current control unit 342 in common. In the latter case, the plasma control unit 341 and the electric current control unit 342 are configured to individually control each of the coil segments 32a and 32b.

Further, in the above description, the plasma processing apparatus is exemplified by a parallel-plate type. However, the embodiment described above may be applied to a plasma processing apparatus of an Inductive Coupled Plasma (ICP) type. Further, the plasma processing apparatus has been described by taking a plasma etching apparatus as an example. However, the embodiment described above may be applied to a film formation apparatus using plasma, such as a plasma Chemical Vapor Deposition (CVD) apparatus.

In the embodiment, the electromagnet controller 34 executes control to cause pulsed electric currents, in each of which its direction and ON/OFF are pulsed, to flow thorough the plurality of coils 32 of the electromagnet 30, which is arranged at an arbitrary position of the chamber 11 of the plasma processing apparatus 10. At this time, the electromagnet controller 34 causes the pulsed electric currents to flow so as to generate first state plasma and second state plasma alternately. Consequently, during the time period of performing a plasma process, the plasma density can be made uniform on average. Further, the result of the plasma process performed to the substrate 100 at a position where plasma is not uniform by the first state plasma becomes opposite in direction relative to the result of the plasma process performed to the substrate 100 at the position where plasma is not uniform by the second state plasma, and thus these results are offset each other. As a result, it is possible to give a desired result to the substrate 100 even in a state where the plasma density is not made uniform.

For example, during a plasma etching process, pulsed electric currents are caused to flow such that the first state plasma forms holes on the peripheral side of the substrate 100 to be directed outward relative to the processing face, and the second state plasma forms holes on the peripheral side of the substrate 100 to be directed inward relative to the processing face. Further, the first state plasma and the second state plasma are switched in a short time as compared with the total time of the etching process, and thus holes can be formed in a state almost perpendicular to the processing face.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma processing apparatus comprising:
a chamber;
a substrate stage configured to support a substrate inside the chamber;
a plasma generation structure configured to generate plasma processing the substrate, in a space above the substrate inside the chamber;
an electromagnet including coils configured to apply a magnetic field to the space; and
an electromagnet controller configured to cause pulsed electric currents, in each of which its direction and ON/OFF are pulsed, to flow through the coils.

2. The plasma processing apparatus according to claim 1, wherein the electromagnet controller is configured to cause the pulsed electric currents to flow through the coils in synchronism with each other.

3. The plasma processing apparatus according to claim 2, wherein the electromagnet controller is configured to control the pulsed electric currents in accordance with sequence control information that prescribes the direction and ON/OFF of each of the pulsed electric currents in a predetermined period for each of the coils, such that the coils have starting time points of the predetermined period in synchronism with each other.

4. The plasma processing apparatus according to claim 3, wherein the electromagnet controller is configured to repeatedly execute control over the pulsed electric currents prescribed in the predetermined period, by using the predetermined period as one cycle.

5. The plasma processing apparatus according to claim 3, wherein
the predetermined period includes a first period and a second period following the first period, and
the sequence control information prescribes the direction and ON/OFF of each of the pulsed electric currents such that the first period is set to have ions, which are being emitted from inside the plasma to the substrate, in a state tilted in a first direction not perpendicular to a processing face of the substrate, and the second period is set to have the ions in a state tilted in a second direction opposite to the first direction.

6. The plasma processing apparatus according to claim 1, wherein the electromagnet is arranged above a top face of the chamber.

7. The plasma processing apparatus according to claim 6, wherein the electromagnet includes the coils that have ring shapes and are arranged in a concentric state.

8. The plasma processing apparatus according to claim 7, wherein each of the coils is divided into an n-number of arc-shaped coil segments, where “n” is an integer of 2 or more.

9. The plasma processing apparatus according to claim 1, wherein the electromagnet is arranged around a lateral face of the chamber.

10. The plasma processing apparatus according to claim 9, wherein the electromagnet includes the coils that have ring shapes and are arranged in a concentric state.

11. The plasma processing apparatus according to claim 10, wherein each of the coils is divided into an n-number of arc-shaped coil segments, where “n” is an integer of 2 or more.

12. The plasma processing apparatus according to claim 3, wherein the electromagnet controller includes
a plasma control unit configured to cause an electric current to flow through one of the coils, and to change a direction of the electric current,
an electric current control unit configured to switch ON/OFF of the electric current flowing through a wiring line between the plasma control unit and the one of the coils, by a bias voltage at the wiring line, and
a sequence control unit configured to control the plasma control unit and the electric current control unit, in accordance with the sequence control information.

13. An etching method comprising:
supporting a substrate on a substrate stage inside a chamber;
generating plasma processing the substrate, in a space above the substrate inside the chamber; and
performing an etching process to the substrate, while applying a magnetic field to the space by causing pulsed electric currents, in each of which its direction and ON/OFF are pulsed, to flow through a coils of an electromagnet.

14. The etching method according to claim 13, wherein, in the performing the etching process, the pulsed electric currents are caused to flow through the coils in synchronism with each other.

15. The etching method according to claim 14, wherein, in the performing the etching process, the pulsed electric currents are controlled in accordance with sequence control information that prescribes the direction and ON/OFF of each of the pulsed electric currents in a predetermined period for each of the coils, such that the coils have starting time points of the predetermined period in synchronism with each other.

16. The etching method according to claim 15, wherein, in the performing the etching process, control over the pulsed electric currents prescribed in the predetermined period is repeatedly executed by using the predetermined period as one cycle.

17. The etching method according to claim 15, wherein
the predetermined period includes a first period and a second period following the first period, and
the sequence control information prescribes the direction and ON/OFF of each of the pulsed electric currents such that the first period is set to have ions, which are being emitted from inside the plasma to the substrate, in a state tilted in a first direction not perpendicular to a processing face of the substrate, and the second period is set to have the ions in a state tilted in a second direction opposite to the first direction.

18. The etching method according to claim 13, wherein the electromagnet is arranged above a top face of the chamber.

19. The etching method according to claim 18, wherein the electromagnet includes the coils that have ring shapes and are arranged in a concentric state.

20. The etching method according to claim 19, wherein each of the coils is divided into an n-number of arc-shaped coil segments, where “n” is an integer of 2 or more.
